(19) United States
(12) Patent Application Publication
(10) Pub. No.: US 2006/0118759 A1
(43) Pub. Date: Jun. 8, 2006

(54) Etching pastes for titanium oxide surfaces

(76) Inventors: Sylke Klein, Rossdorf (DE); Armin Kubelbeck, Bensheim (DE); Werner Stockum, Reinheim (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 10/524,847

(22) PCT Filed: Jul. 30, 2003
(86) PCT No.: PCT/EP03/08395

§ 371 Date: Feb. 18, 2005

(30) Foreign Application Priority Data
Aug. 26, 2002 (DE) 102 39 656.6

(51) Int. Cl. C09K 13/00; B44C 1/22; C23F 1/00

(52) U.S. Cl. 252/79.1; 216/83; 216/100

(57) ABSTRACT

The present invention relates to novel etching media in the form of printable and dispensable etching pastes for the etching of titanium oxide surfaces of the general composition TiₓO_{y}, and to the use of these etching pastes in a process for the etching of titanium oxide surfaces

The present invention relates to novel etching media in the form of printable and dispensable etching pastes for the etching of titanium oxide surfaces of the general composition TiₓO_{y}, and to the use of these etching pastes.

The term titanium oxide surfaces is taken to mean surfaces consisting of titanium and oxygen TiₓO_{y}, in particular compounds of titanium oxide TiO (x, y=1), titanium dioxide TiO₂ (x=1, y=2), dititanium trioxide Ti₂O₃ (x=2, y=3) and non-stoichiometric titanium-oxygen compounds. The oxidic compounds of titanium can be either in glass-like (=amorphous) form or in crystalline or partially crystalline form.

The term glasses as used hereinafter is taken to mean titanium- and oxygen-containing materials which are in the non-crystallised solid amorphous aggregate state and have a high degree of disorder in the microstructure owing to the lack of a long-range order. Layers of amorphous materials of this type can be produced, for example, by hydrolysis of titanium halides, such as TiCl₄, hydrolysis or pyrolysis of organotitanium precursors, such as tetraisopropyl orthotitanate, in an APCVD process [1], or low-pressure- or plasma-supported CVD process (LP- or PE-CVD) [2]. Partially crystalline layers can also be formed here.

Crystalline compounds are the TiO₂ modifications rutile, anatase and brookite, the TiO modification which is isotypical of rock salt, and Ti₂O₃, which crystallises in the corundum lattice structure.

The invention relates both to the etching of titanium- and oxygen-containing crystalline, partially crystalline or amorphous surfaces TiₓO_{y} of uniform solid non-porous and porous solids and to the etching of surfaces of non-porous and porous TiₓO_{y} layers of variable thickness which have been produced on other substrates (for example ceramics, metal sheeting, silicon wafers) by various processes known to the person skilled in the art (for example CVD, PVD, spray/spin-on/off of Ti-O-containing precursors).

### PRIOR ART

Highly efficient crystalline silicon solar cells having efficiencies of >16% usually have a structured, passivated front side with an antireflection coating and two-stage emitter and a passivated reverse side with reflective back-surface contacts and local back surface field (BSF).

In order to produce the two-stage emitter or a local BSF, it is necessary to open the antireflection layer on the front side or reverse side and subsequently to dope the opened areas. These antireflection layers can consist of, for example, titanium oxide—generally TiₓO_{y} (for example TiO₂ having a refractive index of n=2.3)—silicon nitride or silicon dioxide.

The opening of silicon dioxide and silicon nitride layers is described in detail in DE10101926.

In accordance with the current state of the art, any desired structures can be etched selectively in the surfaces and layers directly by laser-supported etching processes [3] or, after masking, by wet-chemical [4, 5] or dry etching processes [6].

However, these processes are generally too complex and expensive for the mass production of solar cells and therefore have not been employed to date.

In laser-supported etching processes, the laser beam scans over the entire etch pattern dot by dot on the surface, which, besides a high degree of precision, also requires considerable adjustment effort and time. In more recent laboratory developments, optical microlenses arranged in the form of an array are used to split the laser beam and to produce a series of punctiform openings in the antireflection layer in an arrangement corresponding to the array [7].

The wet-chemical and dry etching processes include material-intensive, time-consuming and expensive process steps:

A. Masking of the Areas Not to be Etched, for Example by:

photolithography: production of a negative or positive of the etch structure (depending on the resist), application of resist to the substrate surface (for example by spin coating with a liquid photoresist), drying of the photoresist, exposure of the resist-coated substrate surface, development, rinsing, optionally drying
   B. Etching of the Structures by:
dip processes (for example wet etching in wet-chemical banks): dipping of the substrates into the etch bath, etching operation, repeated rinsing in H₂O cascade basins, drying
spin-on or spray processes: the etching solution is applied to a rotating substrate or sprayed onto a substrate, etching operation without/with input of energy (for example photoetching, rinsing, drying)
dry etching processes, such as, for example, plasma etching in expensive vacuum equipment or etching with reactive gases in flow reactors
[1] M. Lemiti, J. P. Boyeaux, M. Vernay, H. El. Omari, E. Fourmond, A. Laugier, Proceedings of the 2^{nd} world PV-Conference, Vienna (1998), p. 1471
[2] H. Frey, G. Kienel, Dünnschichttechnologie [Thin Film Technology], VDI-Verlag, Düsseldorf, 1987, p. 183
[3] R. Preu, S. W. Glunz, S. Schäfer, R. Lüdemann, W. Wettling, W. Pfleging, Proceedings of the 16^{th} PVSC, Glasgow, 2000, 1181-84
[4] D. J. Monk, D. S. Soane, R. T. Howe, Thin Solid Films 232 (1993), 1
[5] J. Buhler, F. -P. Steiner, H. Baltes, J. Micromech. Microeng. 7 (1997), R1
[6] M. Kohler , _{”}Ätzverfahren für die Mikrotechnik“ [Etching processes for microtechnology], Wiley VCH 1998
[7] R. Preu, S. W. Glunz, DE19915666

In practice, processes carried out using etching pastes have proven successful in solar technology for the etching of silicon nitride or silicon dioxide layers. The pastes used are, as described in Patent Application DE 101 01 926 A1, printable and dispensable, homogeneous particle-free etching pastes having non-Newtonian flow behaviour. However, these pastes have proven not to be optimal for the etching of titanium oxide layers with respect to etching rate, selectivity and edge sharpness.

The object of the present invention is therefore to provide a novel etching medium for the selective etching of titanium oxide layers which can be employed in a process which takes place with high throughputs and is technologically simple to carry out.

A further object of the present invention is to provide a simple process for the etching of titanium oxide layers.

The object is achieved by a printable and dispensable etching medium in the form of an etching paste having non-Newtonian; preferably thixotropic flow behaviour for the etching of amorphous, crystalline or partially crystalline surfaces of titanium oxides which is effective at 15-50° C. and/or can be activated by input of energy and comprises the following components:
a) as etching component, ammonium hydrogen difluoride in a concentration of 8.5-9.5% by weight, based on the total amount
b) optionally at least one inorganic and/or organic acid having a content of 24-26% by weight, based on the total amount of the medium, where the organic acid present can be an organic acid having a pKₐ value of between 0 to 5 selected from the group consisting of carboxylic acids, such as formic acid, acetic acid, dichloroacetic acid, lactic acid and oxalic acid,
c) a solvent selected from the group consisting of water, ethers, such as ethylene glycol monobutyl ether, triethylene glycol monomethyl ether, esters of carbonic acid, such as propylene carbonate, ketones, such as 1-methyl-2-pyrrolidone, as such or mixtures thereof in an amount of 52-57% by weight, based on the total amount of the etching medium,
d) 10.5-11.5% by weight, based on the total amount of the etching medium, of cellulose derivatives and/or polymers, such as polyvinyl-pyrrolidone, as thickener,
e) optionally 0-0.5% by weight, based on the total amount, of additives selected from the group consisting of antifoams, thixotropic agents, flow-control agents, deaeration agents and adhesion promoters.

The present invention therefore also relates to an etching medium which comprises ammonium hydrogen difluoride as etching component for oxidic surfaces, ethylene glycol monobutyl ether, triethylene glycol monomethyl ether, propylene carbonate and water as solvents, formic acid as organic acid and polyvinylpyrrolidone as thickener.

Amorphous, crystalline or partially crystalline surfaces of titanium oxides can be etched according to the invention in a process which is simple to carry out by applying an etching medium of this type to a surface to be etched and removing it again after an exposure time of 0.1-15 min.

The etching medium can for this purpose be applied over the entire surface or specifically in accordance with the etch structure mask only to the areas where etching is desired and, when etching is complete, rinsed off using a solvent or solvent mixture or fired in a furnace.

In particular, the etching media can be applied to the surfaces to be etched by screen, template, pad, stamp, ink-jet and manual printing processes and the dispensing technique.

In this way, the etching media according to the invention can be used for the production of marks and labels and for improving the adhesion of TiₓO_{y} glasses, ceramics and other TiₓO_{y}-based systems to other materials by roughening.

The etching media according to the invention can advantageously be used for the etching of amorphous, partially crystalline and crystalline TiₓO_{y} systems in the form of uniform solid non-porous and porous solids or corresponding non-porous and porous layers of variable thickness which have been produced on other substrates.

The etching pastes according to the invention can be employed with particularly good results in the process for the production of solar cells for the removal of amorphous, partially crystalline and crystalline TiₓO_{y} layers, for the selective opening of antireflection layers comprising TiₓO_{y} systems for the production of two-stage selective emitters and/or local p⁺ back surface fields.

The present invention thus also relates to amorphous, partially crystalline or crystalline surfaces of titanium oxides which have been treated with the novel etching media according to the invention of the above-mentioned composition.

### DESCRIPTION

The invention relates to printable and dispensable etching pastes which are suitable for the etching of titanium oxide surfaces, of the general formula TiₓO_{y} and their layers of variable thickness, and to the use thereof in a—compared with the conventional wet and dry etching processes—inexpensive, continuous and technologically simple printing or dispensing/etching process which is suitable for high throughputs.

The printable and dispensable etching pastes described in accordance with the invention are—compared with liquid etchants for TiₓO_{y}-based systems, such as inorganic mineral acids (hydrofluoric acid, hot concentrated sulfuric acid) and caustic lyes/basic etchants (molten alkali metal hydroxides and carbonates)—significantly simpler and safer to handle using less etchant.

The printable and dispensable etching pastes described in accordance with the invention are applied to the TiₓO_{y} surface to be etched in a single process step. A technique with a high degree of automation and high throughput which is suitable for transfer of the etching paste to the surface to be etched is the printing and dispensing technique. In particular, screen, template, pad, stamp and ink-jet printing processes are printing processes which are known to the person skilled in the art.

Depending on the screen, template, klischee or stamp design or the cartridge and dispenser addressing, it is possible to apply the printable and dispensable etching pastes described in accordance with the invention selectively in accordance with the etch structure mask only to the areas where etching is desired or alternatively over the entire surface. All masking and lithography steps as described under A) are rendered superfluous by selective application. The etching operation takes place with or without additional input of energy, for example in the form of heat radiation (using an IR lamp, up to a lamp temperature of about 300° C.). After etching is complete, the printable and dispensable etching pastes are rinsed off the etched surface using a suitable solvent or are removed by firing.

Through variation of the following parameters, the etch depth in TiₓO_{y}-based systems and layers thereof of variable thickness and, in selective structure etching, additionally the edge sharpness of the etch structures can be set:
concentration and composition of the etching component
concentration and composition of the solvents employed
concentration and composition of the thickener system
concentration and composition of any acids added
concentration and composition of any additives added, such as anti-foams, thixotropic agents, flow-control agents, deaeration agents and adhesion promoters
viscosity of the printable and dispensable etching pastes described in accordance with the invention
etching duration with or without input of energy to the surfaces printed with the respective etching paste.

The etching duration can be between a few seconds and several minutes, depending on the application, desired etch depth and/or edge sharpness of the etch structures.

The printable and dispensable etching pastes have the following composition:
etching component(s) for TiₓO_{y} systems and layers thereof
solvents
thickeners
optionally organic and/or inorganic acids
optionally additives, such as, for example, antifoams, thixotropic agents, flow-control agents, deaeration agents and adhesion promoters.

The etching action of the printable and dispensable etching pastes described in accordance with the invention on surfaces of TiₓO_{y}-based systems is based on the use of solutions of ammonium hydrogen difluoride with or without addition of acid. These etching pastes are effective even at room temperature or become effective through additional input of energy (for example heat radiation through an IR lamp, up to a lamp temperature of about 300° C.).

The proportion of etching component employed is in a concentration range 8.5-9.5% by weight, based on the total amount of etching paste.

Suitable inorganic and/or organic solvents and/or mixtures thereof can be:
water
ethers, such as ethylene glycol monobutyl ether, triethylene glycol monomethyl ether
esters of carbonic acid, such as propylene carbonate
organic acids, such as formic acid, acetic acid, lactic acid or the like.

The proportion of solvents is in the range 52-57% by weight, based on the total amount of etching paste.

The viscosity of the printable and dispensable etching pastes described in accordance with the invention is achieved through network-forming thickeners which swell in the liquid phase and can be varied depending on the desired area of application.

The printable and dispensable etching pastes described in accordance with the invention include all etching pastes which do not have constant viscosity at different shear rates, in particular etching pastes having a shear-thinning action. The network produced by thickeners collapses under a shear load. Restoration of the network can take place without a time delay (non-Newtonian etching pastes having plastic or pseudoplastic flow behaviour) or with a time delay (etching pastes having thixotropic flow behaviour).

The thickener polyvinylpyrrolidone (PVP) or various celluloses can be employed individually and/or in combinations with one another. The proportion of thickeners necessary for targeted setting of the viscosity range and basically for the formation of a printable and dispensable paste is in the range 10.5-11.5% by weight, based on the total amount of etching paste.

Organic and inorganic acids whose pKₐ value lie between 0-5 can be added to the printable and dispensable etching pastes described in accordance with the invention. Inorganic acids, such as, for example, hydro-chloric acid, phosphoric acid, sulfuric acid, nitric acid, and also organic acids, in particular formic acid, improve the etching action of the printable and dispensable etching pastes. On addition of acid, the proportion of acid(s) is 24-26% by weight, based on the total amount of etching paste.

Additives having advantageous properties for the desired purpose are antifoams (for example TEGO® Foamex N), thixotropic agents (for example BYK® 410, Borchigel® Thixo2), flow-control agents (for example TEGO® Glide ZG 400), deaeration agents (for example TEGO® Airex 985) and adhesion promoters (for example Bayowet® FT 929). These can have a positive effect on the printability of the etching paste. The proportion of additives is in the range 0-0.5% by weight, based on the total amount of etching paste.

Areas of application for the etching pastes according to the invention are in the solar-cell industry, in particular in the production of photovoltaic components, such as solar cells, or of photodiodes.

The etching pastes which are printable and dispensable in accordance with the invention can be employed, in particular, in all cases where full-area and/or structured etching of surfaces of TiₓO_{y}-based systems is desired.

Thus, entire surfaces, but also selectively individual structures in uniformly solid non-porous and porous TiₓO_{y}-based systems, can be etched to the desired depth. Areas of application are the specific surface etching of TiₓO_{y}-based systems for:
marking and labelling purposes
improvement in the adhesion of TiₓO_{y} glasses, ceramics and other TiₓO_{y}-based systems to other materials by roughening.

The etching pastes which are printable in accordance with the invention can be employed, in particular, in all cases where full-area and/or structured etching of TiₓO_{y} layers is desired.

Additional areas of application are all etching steps on TiₓO_{y} layers which result in the production of photovoltaic components, such as solar cells, photodiodes and the like, in particular the selective opening of TiₓO_{y} layers for the production of:
two-stage selective emitters (after opening production of n⁺⁺ layers) and/or
local p⁺ back surface fields (after opening production of p⁺ layers) and/or
conductive contact structures in the opened structures (for example by electroless deposition).

In particular, screen, template, pad and ink-jet printing processes and the dispensing technique are suitable techniques for application of the etching pastes in the desired manner. In general, manual application is also possible.

For better understanding and in order to illustrate the invention, examples of an etching pastes are given below. These examples are not suitable for restricting the scope of protection of the present application merely thereto, since it is readily possible for the person skilled in the art to carry out a wide variety of variations of the invention and to replace individual components of the compositions with ones having an identical action. It is also readily possible for him to carry out the given examples in a suitable manner in modified form and likewise to come to the desired result.

### EXAMPLE 1

5 g of ethylene glycol monobutyl ether

15 g of triethylene glycol monomethyl ether

15 g of propylene carbonate

7 g of water

27 g of 35% NH₄HF₂ solution

28 g of formic acid

12 g of polyvinylpyrrolidone

The solvent mixture and acid are introduced into a PE beaker. The NH₄HF₂ solution is subsequently added. This is followed by successive addition of the thickener with stirring (about 900 rpm). Transfer into containers is carried out after a short standing time. This standing time is necessary in order that the bubbles formed in the etching paste are able to dissolve.

These mixtures give etching pastes with which TiₓO_{y}-based systems and layers thereof can be etched specifically to a desired depth over the entire surface or in structures with and/or without input of energy.

The measured etching rates on a TiₓO_{y} layer produced by APCVD are dependent on the salt and acid concentration and are between 20-150 nm/min for application in line form. They are, for example, 70 nm/min at room temperature, 140 nm/min at an etching temperature of 50° C., for selective application (line width of 250 μm) as described in Example 1.

The resultant etching paste is stable on storage, easy to handle and printable. It can be removed from the printed material or from the paste support (screen, doctor blade, template, stamp, klischee, cartridge, dispenser, etc.), for example, using water or removed by firing in an oven.

The following etching pastes can be prepared analogously to the etching paste described by Example 1:

### EXAMPLE 2

35.6 g of ethylene glycol monobutyl ether

142.4 g of lactic acid

12 g of NH₄HF₂

10 g of ethylcellulose

### EXAMPLE 3

10 g of triethylene glycol monomethyl ether

50 g of 20% NH₄HF₂ solution

50 g of 1% Deuteron XG stock paste (paste based on an anionic heteropolysaccharide or paste of a high-molecular-weight polymer compound based on xanthan galactomannane)

### EXAMPLE 4

24 g of triethylene glycol monomethyl ether

50 g of 20% NH₄HF₂ solution

8 g of formic acid

1.5 g of Tylose 4000 (hydroxyethylcellulose)

### EXAMPLE 5

8 g of ethylene glycol monobutyl ether

14 g of propylene carbonate

14 g of triethylene glycol monomethyl ether

34 g of 20% NH₄HF₂ solution

28 g of dichloroacetic acid

10 g of polyvinylpyrrolidone K90

1. Printable and dispensable etching medium in the form of an etching paste having non-Newtonian, preferably thixotropic flow behaviour for the etching of amorphous, crystalline or partially crystalline surfaces of titanium oxides, characterised in that it is effective at 15-50° C. and/or can be activated by the input of energy and comprises the following components:
a) as etching component, ammonium hydrogen difluoride in a concentration of 8.5-9.5% by weight, based on the total amount
b) optionally at least one inorganic and/or organic acid having a content of 24-26% by weight, based on the total amount of the medium, where the organic acid present can be an organic acid having a pKₐ value of between 0 and 5 selected from the group consisting of carboxylic acids, such as formic acid, acetic acid, dichloroacetic acid, lactic acid and oxalic acid,
c) a solvent selected from the group consisting of water, ethers, such as ethylene glycol monobutyl ether, triethylene glycol monomethyl ether, esters of carbonic acid, such as propylene carbonate, ketones, such as 1-methyl-2-pyrrolidone, as such or mixtures thereof in an amount of 52-57% by weight, based on the total amount of the etching medium,
d) 10.5-11.5% by weight, based on the total amount of the etching medium, of cellulose derivatives and/or polymers, such as polyvinylpyrrolidone, as thickener,
e) optionally 0-0.5% by weight, based on the total amount, of additives selected from the group consisting of antifoams, thixotropic agents, flow-control agents, deaeration agents and adhesion promoters.

2. Etching medium according to claim 1, characterised in that it comprises ammonium hydrogen difluoride as etching component for oxidic surfaces, ethylene glycol monobutyl ether, triethylene glycol monomethyl ether, propylene carbonate and water as solvents, formic acid as organic acid and polyvinylpyrrolidone as thickener.

3. Process for the etching of amorphous, crystalline or partially crystalline surfaces of titanium oxides, characterised in that an etching medium according to claim 1 is applied to the surface to be etched and is removed again after an exposure time of 0.1-15 minutes.

4. Process according to claim 3, characterised in that the etching medium is applied over the entire surface or specifically in accordance with the etch structure mask only to the areas where etching is desired, and, when etching is complete, is rinsed off using a solvent or solvent mixture or fired in a furnace.

5. Use of an etching medium according to claim 1 for the production of marks and labels and for improving the adhesion of TiₓO_{y} glasses, ceramics and other TiₓO_{y}-based systems to other materials by roughening.

6. Use of an etching medium according to claim 1 in screen, template, pad, stamp, ink-jet and manual printing processes and the dispensing technique.

7. Use of an etching medium according to claim 1 for the etching of amorphous, partially crystalline and crystalline TiₓO_{y} systems, as uniform solid non-porous and porous solids or corresponding non-porous and porous layers of variable thickness which have been produced on other substrates.

8. Use of an etching medium according to claim 1 for the removal of amorphous, partially crystalline and crystalline TiₓO_{y} layers, for the selective opening of antireflection layers comprising TiₓO_{y} systems for the production of two-stage selective emitters and/or local p⁺ back surface fields in solar cells.

9. Amorphous, partially crystalline or crystalline surfaces of titanium oxides which have been treated with etching media according to claim 1.
